(19) United States
(12) Patent Application Publication
(10) Pub. No.: US 2017/0093376 A1
(43) Pub. Date: Mar. 30, 2017

(54) CURRENT SOURCE CIRCUIT

(71) Applicant: Kabushiki Kaisha Toshiba, Tokyo (JP)

(72) Inventor: Hirokazu Kadowaki, Fujisawa Kanagawa (JP)

(21) Appl. No.: 15/063,699

(22) Filed: Mar. 8, 2016

(30) Foreign Application Priority Data
Sep. 29, 2015 (JP) 2015-191112

(51) Int. Cl. H03K 3/012; H03K 17/687

(52) U.S. Cl. CPC H03K 3/012; H03K 17/6871; H03K 2017/6875

(57) ABSTRACT

According to embodiments, a source of a first MOS transistor is connected to a power supply, and a gate and a drain thereof are connected to each other. A source of a second MOS transistor is connected to the power supply, and a gate thereof is connected to the gate of the first MOS transistor. A drain of a third MOS transistor is connected to the drain of the first MOS transistor, and a gate thereof is connected to a drain of the second MOS transistor. A drain of a fourth MOS transistor is connected to the drain of the second MOS transistor and the gate of the third MOS transistor, and a gate of the fourth MOS transistor is connected to a source of the third MOS transistor. A current value setting element is located between the source of the third MOS transistor and the ground.

### CROSS REFERENCE TO RELATED APPLICATIONS

This application is based upon and claims the benefit of priority from Japanese Patent Application No. 2015-191112, filed on Sep. 29, 2015; the entire contents of which are incorporated herein by reference.

### FIELD

The embodiments of the present invention relate to a current source circuit.

### BACKGROUND

An integrated circuit comprises, for example, a current source circuit for generating and outputting operating currents of circuitry, and this current source circuit comprises, for example, a current value setting element for setting the values of the operating currents. As this current value setting element, a resistor element or a depletion-type MOS transistor, for example, is used.

In recent years, an integrated circuit is used at a high power supply voltage in some cases, and low power consumption is required even in such cases. Hence, an operating current is conceivably decreased. In a case where a resistor element is intended to be used as the current value setting element, however, a resistor element having an extremely large resistance value of, for example, several hundred ML is necessary, in order to decrease the operating current. In this case, the area of the resistor element that accounts for the area of the current source circuit increases significantly. The resistor element therefore has difficulty being put into practical use.

On the other hand, in a case where a depletion-type MOS transistor is intended to be used as the current value setting element, the MOS transistor is unlikely to be used as the current value setting element if the power supply voltage is high, since the withstand voltage of the MOS transistor is generally low.

An object of the present embodiment is to provide a current source circuit capable of suppressing power consumption even if a power supply voltage is high.

### BRIEF DESCRIPTION OF THE DRAWINGS

FIG. 1 is a circuit diagram of a current source circuit according to a first embodiment;

FIG. 2 is a cross-sectional view illustrating a schematic structure of a third MOS transistor and a fourth MOS transistor; and

FIG. 3 is a circuit diagram of a current source circuit according to a second embodiment.

### DETAILED DESCRIPTION OF THE INVENTION

Embodiments will now be explained with reference to the accompanying drawings. The present invention is not limited to the embodiments.

### First Embodiment

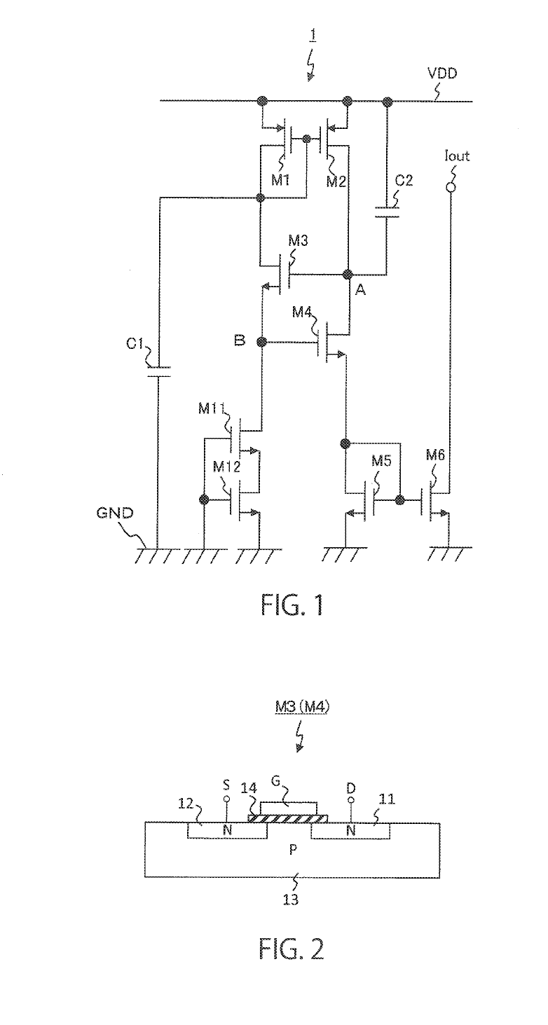

FIG. 1 is a circuit diagram of a current source circuit according to a first embodiment. As illustrated in FIG. 1, a current source circuit 1 according to the present embodiment comprises a first MOS transistor M1; a second MOS transistor M2; a third MOS transistor M3; a fourth MOS transistor M4; a fifth MOS transistor M5; a sixth MOS transistor M6; a first depletion-type MOS transistor M11; a second depletion-type MOS transistor M12; a first capacitor C1; and a second capacitor C2.

The first MOS transistor M1 and the second MOS transistor M2 are enhancement-type P-channel MOSFETs. The withstand voltages of the first MOS transistor M1 and the second MOS transistor M2 are higher than the voltage of a power supply VDD. In addition, the first MOS transistor M1 and the second MOS transistor M2 are composed of a current mirror circuit.

Specifically, a source of M1 is connected to the power supply VDD and a gate and a drain of the first MOS transistor M1 are connected to each other. On the other hand, a source of the second MOS transistor M2 is connected to the power supply VDD and a gate of the second MOS transistor M2 is connected to the gate of the first MOS transistor M1.

The third MOS transistor M3 and the fourth MOS transistor M4 are enhancement-type N-channel MOSFETs. The withstand voltages of the third MOS transistor M3 and the fourth MOS transistor M4 are also higher than the voltage of the power supply VDD.

A drain of the third MOS transistor M3 is connected to the drain of the first MOS transistor M1, and a gate of the third MOS transistor M3 is connected to the drain of the second MOS transistor M2.

On the other hand, a drain of the fourth MOS transistor M4 is connected to the drain of the second MOS transistor M2 and the gate of the third MOS transistor M3, and a gate of the fourth MOS transistor M4 is connected to the source of the third MOS transistor.

FIG. 2 is a cross-sectional view illustrating a schematic structure of the third MOS transistor M3 and the fourth MOS transistor M4.

The third MOS transistor M3 and the fourth MOS transistor M4 include a first N-type semiconductor region 11, a second N-type semiconductor region 12, a P-type semiconductor region 13, and a gate oxide film 14. The first N-type semiconductor region 11 functions as the drain. The second N-type semiconductor region 12 functions as the source. The P-type semiconductor region 13 is opposed to the gate across the gate oxide film 14 between the first N-type semiconductor region 11 and the second N-type semiconductor region 12.

In FIG. 2, a leakage current flows between the first N-type semiconductor region 11 and the P-type semiconductor region 13. In the present embodiment, the leakage current of the fourth MOS transistor M4 is smaller than leakage current of the third MOS transistor M3.

Referring back to FIG. 1, the fifth MOS transistor M5 and the sixth MOS transistor M6 are also enhancement-type N-channel MOSFETs. The fifth MOS transistor M5 and the sixth MOS transistor M6 are composed of a current mirror circuit.

Specifically, both a drain and a gate of the fifth MOS transistor M5 are connected to the source of the fourth MOS transistor M4, and a source of the fifth MOS transistor M5 is connected to a ground (GND) serving as a reference potential. On the other hand, a drain of the sixth MOS transistor M6 is connected to an output terminal Iout, a gate of the sixth MOS transistor M6 is connected to the gate of the fifth MOS transistor M5, and a source of the sixth MOS transistor M6 is connected to the ground.

The first depletion-type MOS transistor M11 and the second depletion-type MOS transistor M12 are depletion-type N-channel MOSFETs. That is, the first depletion-type MOS transistor M11 and the second depletion-type MOS transistor M12 are MOSFETs which flow a current between the drain and the source even if the potential of the gate is 0 volt.

The gate of the first depletion-type MOS transistor M11 is connected to the ground, the drain of the first depletion-type MOS transistor M11 is connected to the source of the third MOS transistor M3 and the gate of the fourth MOS transistor M4, and the source of the first depletion-type MOS transistor M11 is connected to the drain of the second depletion-type MOS transistor M12.

On the other hand, the gate of the second depletion-type MOS transistor M12 is connected to the ground, the drain of the second depletion-type MOS transistor M12 is connected to the source of the first depletion-type MOS transistor M11, and the source of the second depletion-type MOS transistor M12 is connected to the ground. That is, the second depletion-type MOS transistor M12 is connected in series with the first depletion-type MOS transistor M11.

In the present embodiment, the first depletion-type MOS transistor M11 and the second depletion-type MOS transistor M12 function as a current value setting element for setting the value of current output from the output terminal Iout. The number of depletion-type MOS transistors is not limited to two, however, but may be one or three or more.

In addition, the above-described fourth MOS transistor M4 is composed of a first transistor to set a voltage to be applied to the above-described current value setting element and output a current based on the value of current set by the current value setting element.

Likewise, the above-described third MOS transistor M3 is composed of a second transistor to apply a voltage to the control terminal (gate) of the first transistor and electrically connect to the current value setting element, so that the first transistor passes the above-described current.

In addition, the above-described first MOS transistor M1 and the above-described second MOS transistor M2 are connected to the control terminal (gate) of the second transistor and one end (drain) of the first transistor and are composed of a current mirror circuit to output a current corresponding to the abovementioned current.

The first capacitor C1 is disposed between the drain of the first MOS transistor M1 and the ground. The first capacitor C1 functions as means for turning on the first MOS transistor M1 to flow the charging current of the first capacitor C1 itself through a node A by way of the first MOS transistor M1, thereby assisting the potential rise of the node A. Here, the node A refers to a location of connection of the drain of the second MOS transistor M2, the gate of the third MOS transistor M3 and the drain of the fourth MOS transistor M4.

The second capacitor C2 is disposed between the power supply VDD and the gate of the third MOS transistor M3. The second capacitor C2 functions as means for stabilizing the on-state of the third MOS transistor M3.

The current source circuit 1 according to the present embodiment is configured to include both the first capacitor C1 and the second capacitor C2, but may be configured to include at least one of the capacitors C1 and C2.

Here, a location of connection of the source of the third MOS transistor M3, the gate of the fourth MOS transistor M4 and the drain of the first depletion-type MOS transistor M11 is likewise referred to as a node B. Hereinafter, a potential VA of the node A and a potential VB of the node B will be described.

The potential VA of the node A is represented by expression (1) shown below:

VA=VB+Vgs3 (1)

In expression (1) shown above, Vgs3 is the gate-source voltage of the third MOS transistor M3. The gate-source voltage Vgs3 of the third MOS transistor M3 is represented by expression (2) shown below:

$$Vgs 3 = Vth 3 + \sqrt{( \frac{2 \cdot L 3 \cdot Ids 3}{μ n \cdot Cox 3 \cdot W 3} )} \qquad ( 2 )$$

In expression (2) shown above, Vth3 is the threshold voltage of the third MOS transistor M3. L3 is the gate length of the third MOS transistor M3. Ids3 is the drain-source current of the third MOS transistor M3. μn is electron mobility. Cox3 is the capacitance value of the gate oxide film 14 of the third MOS transistor M3. W3 is the gate width of the third MOS transistor M3.

On the other hand, the potential VB of the node B is represented by expression (3) shown below:

VB=Vgs4+Vgs5 (3)

In expression (3) shown above, Vgs4 is the gate-source voltage of the fourth MOS transistor M4, and Vgs5 is the gate-source voltage of the fifth MOS transistor M5.

The gate-source voltage Vgs4 of the fourth MOS transistor M4 is represented by expression (4) shown below:

$$Vgs 4 = Vth 4 + \sqrt{( \frac{2 \cdot L 4 \cdot Ids 4}{μ n \cdot Cox 4 \cdot W 4} )} \qquad ( 4 )$$

In expression (4) shown above, Vth4 is the threshold voltage of the fourth MOS transistor M4. L4 is the gate length of the fourth MOS transistor M4. Ids4 is the drain-source current of the fourth MOS transistor M4. μn is electron mobility. Cox4 is the capacitance value of the gate oxide film 14 of the fourth MOS transistor M4. W4 is the gate width of the fourth MOS transistor M4.

The gate-source voltage Vgs5 of the fifth MOS transistor M5 is represented by expression (5) shown below:

$$Vgs 5 = Vth 5 + \sqrt{( \frac{2 \cdot L 5 \cdot Ids 5}{μ n \cdot Cox 5 \cdot W 5} )} \qquad ( 5 )$$

In expression (5) shown above, Vth5 is the threshold voltage of the fifth MOS transistor M5. L5 is the gate length of the fifth MOS transistor M5. Ids5 is the drain-source current of the fifth MOS transistor M5. μn is electron mobility. Cox5 is the capacitance value of the gate oxide film of the fifth MOS transistor M5. W5 is the gate width of the fifth MOS transistor M5.

The potential VB of the above-described node B corresponds to a voltage applied to the first depletion-type MOS transistor M11 and the second depletion-type MOS transistor M12. According to above expression (3), this voltage is determined based on the gate-source voltage of the fourth MOS transistor M4. That is, the current source circuit 1 according to the present embodiment can adjust this voltage using the fourth MOS transistor M4, so that any voltages higher than the withstand voltage are not applied to the first depletion-type MOS transistor M11 and the second depletion-type MOS transistor M12.

The third MOS transistor M3 is provided in order to drive the fourth MOS transistor M4, and the gate potential of this transistor M3 corresponds to the potential VA of the node A. According to expression (1) and expression (3), the potential VA of the node A is determined based on the gate-source voltage of the third MOS transistor M3, the gate-source voltage of the fourth MOS transistor M4 and the gate-source voltage of the fifth MOS transistor M5. Accordingly, it is possible to prevent any voltages higher than the withstand voltage from being applied to the gate of the third MOS transistor M3 by adjusting these gate-source voltages.

Hereinafter, the operation of the current source circuit 1 according to the present embodiment will be described by referring to FIG. 1.

First, the power supply VDD begins to rise from 0 volt to a desired potential. A voltage rise in the power supply VDD causes the potential of the node A to rise to a potential determined by a voltage dividing ratio based on an output resistance Rds2 of the second MOS transistor M2, an output resistance Rds4 of the fourth MOS transistor M4 and an output resistance Rds5 of the fifth MOS transistor M5.

Since electrical charges have not yet accumulated in the first capacitor C1 when the potential of the power supply VDD begins to rise, the drain and the gate of the first MOS transistor M1 remain kept to 0 volt. If the potential of the power supply VDD continues to rise under this condition and the first MOS transistor M1 reaches the value of Vgs1 which is a threshold for the MOS transistor M1 to turn on, the first MOS transistor M1 turns on and a current begins to flow through the first capacitor C1. Note that the third MOS transistor M3 has not yet turned on at this time.

During a period in which the potential of the power supply VDD is rising, a current flows through the first capacitor C1. The same current as this current also begins to flow through the second MOS transistor M2 constituting a current mirror circuit in conjunction with the first MOS transistor M1 and, thereafter, flows into the node A. The fourth MOS transistor M4 has not yet turned on at this time, and therefore, the current flows through the second capacitor C2. As a result, the potential of the node A rises further.

The potential of the node B also rises along with a rise in the potential of the node A. Since the drain potential of the first depletion-type MOS transistor M11 rises at this time, the first depletion-type MOS transistor M11 and the second depletion-type MOS transistor M12 go into a state of being able to pass currents.

If the potential of the node A rises further and the third MOS transistor M3 becomes ready to turn on, a current begins to flow from the first MOS transistor M1 toward the third MOS transistor M3. This current flows through the first depletion-type MOS transistor M11 and the second depletion-type MOS transistor M12 by way of the third MOS transistor M3.

If the current flows through the first MOS transistor M1, the same current as this current also flows through the second MOS transistor M2 constituting a current mirror circuit in conjunction with the first MOS transistor M1. If this current flows into the node A, the potential of the node A rises further. As a result, the potential of the node B also rises and the fourth MOS transistor M4 goes into an on-state.

If the fourth MOS transistor M4 goes into an on-state, a current flows from the second MOS transistor M2 through to the fifth MOS transistor M5. The same current as this current begins to also flow through the sixth MOS transistor M6 constituting a current mirror circuit in conjunction with the fifth MOS transistor M5. Finally, the current flowing through the sixth MOS transistor M6 is distributed to each circuit connected to the output terminal Iout.

According to the current source circuit 1 of the present embodiment described above, it is possible to adjust a voltage to be applied to the first depletion-type MOS transistor M11 and the second depletion-type MOS transistor M12, i.e., a voltage to be applied to the node B, using the fourth MOS transistor M4. Consequently, it is possible to avoid applying a high voltage to the first depletion-type MOS transistor M11 and the second depletion-type MOS transistor M12 even if the voltage of the power supply VDD is high. As a result, it is possible to use a first depletion-type MOS transistor M11 and a second depletion-type MOS transistor M12 having a low withstand voltage. Since these transistors allow a current value to be set to a small value, it is possible to suppress power consumption even under conditions of use where a power supply voltage is high.

In addition, since the current source circuit 1 of the present embodiment comprises the first capacitor C1 disposed between the drain of the first MOS transistor M1 and the ground, the same current as the charging current of the first capacitor C1 also flows through the second MOS transistor M2 constituting a current mirror circuit in conjunction with the first MOS transistor M1, when the first MOS transistor M1 turns on. This makes it easy for the potential of the node A to rise. Consequently, the third MOS transistor M3 securely turns on, and therefore, a current securely flows through the first depletion-type MOS transistor M11 and the second depletion-type MOS transistor M12. Accordingly, the current source circuit 1 can securely output a current.

In addition, since the current source circuit 1 according to the present embodiment is also provided with the second capacitor C2 disposed between the power supply VDD and the gate of the third MOS transistor M3, the certainty for the third MOS transistor M3 to turn on improves. Consequently, a current more securely flows through the first depletion-type MOS transistor M11 and the second depletion-type MOS transistor M12. Accordingly, the current source circuit 1 can more securely output a current.

Furthermore, the current source circuit 1 of the present embodiment comprises the third MOS transistor M3 disposed partway through a first current pathway from the first MOS transistor M1 to the second depletion-type MOS transistor M12. On the other hand, the current source circuit 1 comprises the fourth MOS transistor M4 disposed partway through a second current pathway from the second MOS transistor M2 to the fifth MOS transistor M5.

In the third MOS transistor M3 and the fourth MOS transistor M4, a leakage current may be passed between the first N-type semiconductor region 11 and the P-type semiconductor region 13. If the leakage current of the fourth MOS transistor M4 is large, the leakage current of the second current pathway increases, with the result that a desired current can no longer be output from the current source circuit 1 or the current source circuit 1 itself fails to start up.

In the present embodiment, however, a size of the third MOS transistor M3 and a size of the fourth MOS transistor M4 are substantially same. In this case, the leakage current of the fourth MOS transistor M4 is smaller than the leakage current of the third MOS transistor M3. The leakage current of the second current pathway is therefore smaller than the leakage current of the first current pathway. Accordingly, it is possible to reduce effects that the leakage current of the third MOS transistor M3 may have on the output current of the current source circuit 1. This makes it possible to stably start up the current source circuit 1 and output a desired current. Note that in order to more stably start up the current source circuit 1, the size of the third MOS transistor M3 may be made larger than the size of the fourth MOS transistor, so that the leakage current of the fourth MOS transistor M4 is securely smaller than the leakage current of the third MOS transistor M3.

### Second Embodiment

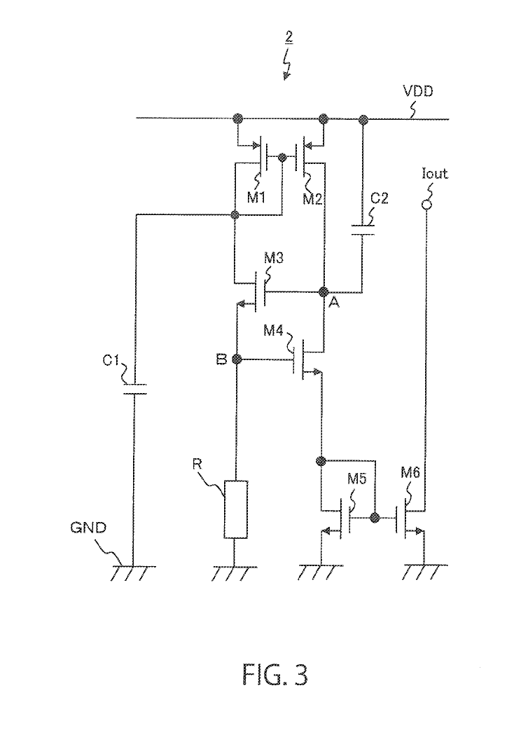

FIG. 3 is a circuit diagram of a current source circuit according to a second embodiment. Elements the same as those of the above-described current source circuit 1 according to the first embodiment are denoted by like reference numerals and characters and will not be described in detail again.

As illustrated in FIG. 3, a current source circuit 2 according to the present embodiment differs from the current source circuit 1 according to the first embodiment in a resistor element R in place of the first depletion-type MOS transistor M11 and the second depletion-type MOS transistor M12.

One end of the resistor element R is connected to the node B, whereas the other end of the resistor element R is connected to the ground. In the present embodiment, the resistor element R functions as a current value setting element for setting the value of current output from the output terminal Iout. A voltage applied to the resistor element R, in other words, the potential of the node B can be adjusted by the fourth MOS transistor M4, as in the first embodiment.

According to the current source circuit 2 in accordance with the present embodiment described above, the potential of the node B can be adjusted using the fourth MOS transistor M4 as in the first embodiment. Accordingly, it is possible to avoid applying a high voltage to the resistor element R even if the voltage of the power supply VDD is high. Consequently, the voltage between both ends of the resistor element R is set low, and therefore, it is possible to decrease the value of current to be set by the resistor element R. That is, it is possible to generate extremely small currents without using any large-area resistor element R. Consequently, it is possible to suppress power consumption.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A current source circuit comprising:
a first MOS transistor whose source is connected to a power supply, and whose gate and drain are connected to each other;
a second MOS transistor whose source is connected to the power supply, and whose gate is connected to the gate of the first MOS transistor;
a third MOS transistor whose drain connected to the drain of the first MOS transistor, and whose gate is connected to a drain of the second MOS transistor;
a fourth MOS transistor whose drain is connected to the drain of the second MOS transistor and the gate of the third MOS transistor, and whose gate is connected to a source of the third MOS transistor; and
a current value setting element located between the source of the third MOS transistor and a ground, wherein
each of the third MOS transistor and the fourth MOS transistor includes a first N-type semiconductor region functioning as the drain, a second N-type semiconductor region functioning as the source, and a P-type semiconductor region disposed between the first N-type semiconductor region and the second semiconductor region and opposed to the gate across a gate oxide film, and
a size of the third MOS transistor is equal to or larger than a size of the fourth MOS transistor.

2. The current source circuit according to claim 1, wherein the current value setting element is composed of one or more depletion-type MOS transistors whose gates are connected to the ground.

3. The current source circuit according to claim 2, wherein the depletion-type MOS transistors include a first depletion-type MOS transistor and a second depletion-type MOS transistor connected in series with the first depletion-type MOS transistor.

4. The current source circuit according to claim 1, wherein the current value setting element is composed of a resistor element.

5. The current source circuit according to claim 1, further comprising:
a fifth MOS transistor whose drain and gate are connected to a source of the fourth MOS transistor, and whose source is connected to the ground; and
a sixth MOS transistor whose drain is connected to an output terminal, whose gate is connected to the gate of the fifth MOS transistor, and whose source is connected to the ground.

6. The current source circuit according to claim 1, further comprising at least one of a first capacitor and a second capacitor, wherein the first capacitor is disposed between the drain of the first MOS transistor and the ground, and the second capacitor is disposed between the power supply and the gate of the third MOS transistor.

7. (canceled)

8. (canceled)

9. A current source circuit including:
an element to set a current value;
a first transistor to set a voltage to be applied to the element and output a current based on the current value;
a second transistor to apply a voltage to a control terminal of the first transistor and electrically connect to the element to pass the current; and
a current mirror circuit to connect to a control terminal of the second transistor and one end of the first transistor and output a current corresponding to the current, wherein
each of the first transistor and the second transistor includes a first N-type semiconductor region functioning as the drain, a second N-type semiconductor region functioning as the source, and a P-type semiconductor region disposed between the first N-type semiconductor region and the second semiconductor region and opposed to the gate across a gate oxide film, and
a size of the second transistor is equal to or larger than a size of the first transistor.

10. The current source circuit according to claim 9, wherein the element is composed of one or more depletion-type MOS transistors whose gates are connected to the ground.

11. The current source circuit according to claim 10, wherein the depletion-type MOS transistors include a first depletion-type MOS transistor and a second depletion-type MOS transistor connected in series with the first depletion-type MOS transistor.

12. The current source circuit according to claim 9, wherein the element is composed of a resistor element.
